(19) United States
(12) Patent Application Publication
(10) Pub. No.: US 2024/0194773 A1
(43) Pub. Date: Jun. 13, 2024

(54) HIGH ELECTRON MOBILITY TRANSISTOR AND METHOD FOR FABRICATING THE SAME

(71) Applicant: Taiwan-Asia Semiconductor Corporation, Hsinchu City (TW)

(72) Inventors: Yen-Chun TSENG, Hsinchu City (TW); Tzu-Wen WANG, Hsinchu City (TW); Chuan-Wei CHEN, Hsinchu City (TW)

(21) Appl. No.: 18/495,128

(22) Filed: Oct. 26, 2023

(30) Foreign Application Priority Data
Dec. 8, 2022 (TW) 111147284

(51) Int. Cl. H01L 29/778; H01L 29/20; H01L 29/205; H01L 29/66

(52) U.S. Cl. CPC H01L 29/7786; H01L 29/2003; H01L 29/205; H01L 29/66462

(57) ABSTRACT

The present invention provides a high electron mobility transistor, which includes a substrate, a buffer layer, a channel layer, a first semiconductor epitaxial structure, a second semiconductor epitaxial structure, a drain, a source and a gate. The first semiconductor epitaxial structure is located on the channel layer and sequentially includes a first aluminum gallium nitride layer, a supply layer and a second aluminum gallium nitride layer, and the first semiconductor epitaxial structure is formed with a hollow part extending from a top surface of the second aluminum gallium nitride layer toward the channel layer. The second semiconductor epitaxial structure is located in the hollow part and sequentially includes an aluminum gallium nitride layer and a P-type gallium nitride layer. The drain and the source are respectively arranged on the second aluminum gallium nitride layer, and the gate is arranged on the P-type gallium nitride layer.

### CROSS-REFERENCES TO RELATED APPLICATIONS

This application claims the benefit of priority to Taiwanese Patent Application No. 111147284 filed on Dec. 8, 2022, which is hereby incorporated by reference in its entirety.

### BACKGROUND OF THE INVENTION

### Field of the Invention

The present invention relates to a transistor device, and in particular to a high electron mobility transistor and a method for fabricating the same.

### Descriptions of the Related Art

The high electron mobility transistor (HEMT) is a field effect transistor that uses semiconductor materials with different energy gaps to form a two-dimensional electron gas (2D electron gas, 2DEG for short) layer at the junction. Due to the high electron mobility of the two-dimensional electron gas, HEMTs can provide advantages such as high breakdown voltage, low resistance, and high electron mobility, and are widely used in high-power electronic devices.

Based on different designs and functions, HEMTs can be divided into the enhancement-mode (E-mode) HEMT and the depletion-mode (D-mode) HEMT. The E-mode HEMT can open the 2DEG channel by applying a positive voltage to the gate to achieve effective control effect. On the other hand, the D-mode HEMT keeps the 2DEG channel open without applying a voltage to the gate but can increase the 2DEG concentration through different designs of the barrier layer (AlGaN layer). Although the aforementioned E-mode HEMT and the D-mode HEMT have their own advantages, they can only exist in their respective structural designs and cannot have both at the same time.

Therefore, how to design a high electron mobility transistor that can have both the aforementioned advantages is a subject worthy of study.

### SUMMARY OF THE INVENTION

The main objective of the present invention is to provide a high electron mobility transistor that combines the advantages of an enhancement-mode HEMT and a depletion-mode HEMT.

To achieve the above objective, the present invention provides a high electron mobility transistor, which includes a substrate, a buffer layer, a channel layer, a first semiconductor epitaxial structure, a second semiconductor epitaxial structure, a drain, a source and a gate. The buffer layer is located on the substrate. The channel layer is located on the buffer layer. The first semiconductor epitaxial structure is located on the channel layer and sequentially includes a first aluminum gallium nitride layer, a supply layer and a second aluminum gallium nitride layer, and the first semiconductor epitaxial structure is formed with a hollow part, and the hollow part extends from a top surface of the second aluminum gallium nitride layer toward the channel layer. The second semiconductor epitaxial structure is located in the hollow part and sequentially includes an aluminum gallium nitride layer and a P-type gallium nitride layer. The drain and the source are respectively arranged on the top surface of the second aluminum gallium nitride layer, and the gate is arranged on the top surface of the P-type gallium nitride layer.

In one embodiment of the present invention, the top surface of the second aluminum gallium nitride layer of the first semiconductor epitaxial structure and the top surface of the P-type gallium nitride layer are not on the same plane.

In one embodiment of the present invention, the top surface of the second aluminum gallium nitride layer of the first semiconductor epitaxial structure and the connection surface between the aluminum gallium nitride layer and the P-type gallium nitride layer of the second semiconductor epitaxial structure are not on the same plane.

In one embodiment of the present invention, the connection surface between the aluminum gallium nitride layer and the P-type gallium nitride layer of the second semiconductor epitaxial structure is not higher than the top surface of the second aluminum gallium nitride layer of the first semiconductor epitaxial structure.

In one embodiment of the present invention, the supply layer is an N-type aluminum gallium nitride layer.

In one embodiment of the present invention, the bottom surface of the hollow part is between the connection surface of the first aluminum gallium nitride layer and the supply layer, and the connection surface of the first aluminum gallium nitride layer and the channel layer.

In one embodiment of the present invention, the thickness of the aluminum gallium nitride layer of the second semiconductor epitaxial structure is from 10 nm to 50 nm, and the thickness of the P-type gallium nitride layer is from 1 nm to 100 nm.

The present invention further discloses a method for fabricating a high electron mobility transistor, including: providing a substrate, providing a buffer layer located on the substrate, providing a channel layer located on the buffer layer, forming a first semiconductor epitaxial structure located on the channel layer, wherein the first semiconductor epitaxial structure sequentially includes a first aluminum gallium nitride layer, a supply layer and a second aluminum gallium nitride layer, forming a hollow part by photolithography etching the first semiconductor epitaxial structure, wherein the hollow part extends from a top surface of the second aluminum gallium nitride layer toward the channel layer, forming a second semiconductor epitaxial structure located in the hollow part, wherein the second semiconductor epitaxial structure sequentially includes an aluminum gallium nitride layer and a P-type gallium nitride layer, forming a drain and a source respectively arranged on the top surface of the second aluminum gallium nitride layer, and forming a gate arranged on the top surface of the P-type gallium nitride layer.

In one embodiment of the present invention, before the step of forming a second semiconductor epitaxial structure located in the hollow part, the method further comprises: forming an oxide layer or a dielectric layer on the first semiconductor epitaxial structure, and removing the oxide layer or the dielectric layer located in the hollow part.

The present invention further provides a method for fabricating a high electron mobility transistor, including: providing a substrate, providing a buffer layer located on the substrate, providing a channel layer located on the buffer layer, sequentially forming an aluminum gallium nitride layer and a P-type gallium nitride layer, removing a part of the P-type gallium nitride layer so that a second semiconductor epitaxial structure is formed by the remaining part of the P-type gallium nitride layer and the aluminum gallium nitride layer under the P-type gallium nitride layer, performing an ion implantation process to form a supply layer in the aluminum gallium nitride layer outside the second semiconductor epitaxial structure for forming a first semiconductor epitaxial structure, wherein the first semiconductor epitaxial structure sequentially includes a first aluminum gallium nitride layer, the supply layer and a second aluminum gallium nitride layer, forming a drain and a source respectively arranged on the top surface of the second aluminum gallium nitride layer, and forming a gate arranged on the top surface of the P-type gallium nitride layer.

In one embodiment of the present invention, before the step of performing the ion implantation process, the method further comprises: forming an oxide layer or a dielectric layer on the second semiconductor epitaxial structure.

Accordingly, the high electron mobility transistor of the present invention can not only increase the electron concentration of 2DEG, but also can effectively control the opening or closing of the transistor by applying a positive voltage. Therefore, the difficulty of the control circuit will be reduced and the high electron mobility transistors of the present invention have the advantages of both depletion-mode HEMTs and enhancement-mode HEMTs.

### BRIEF DESCRIPTION OF THE DRAWINGS

FIG. 1 is a schematic view of the first embodiment of the high electron mobility transistor of the present invention.

FIG. 2 is a schematic view of the second embodiment of the high electron mobility transistor of the present invention.

FIG. 3 is a schematic view of the third embodiment of the high electron mobility transistor of the present invention.

FIG. 4 is a flow chart of the first embodiment of the method for fabricating the high electron mobility transistor of the present invention.

FIG. 5 is a schematic view of the structural fabricating process relative to FIG. 4.

FIG. 6 is a partial flow chart of the second embodiment of the method for fabricating the high electron mobility transistor of the present invention.

FIG. 7 is a flow chart of the third embodiment of the method for fabricating the high electron mobility transistor of the present invention.

FIG. 8 is a schematic view of the structural process relative to FIG. 7.

FIG. 9 is a partial flow chart of the fourth embodiment of the method for fabricating the high electron mobility transistor of the present invention.

### DETAILED DESCRIPTION OF THE PREFERRED EMBODIMENT

Since various aspects and embodiments are only illustrative and non-restrictive, after reading this description, a person with ordinary knowledge may also have other aspects and embodiments without departing from the scope of the present invention. According to the following detailed description and patent application scope, the features and advantages of these embodiments will be more clearly demonstrated.

In this disclosure, “a” or “an” is used to describe the elements and components described herein. This is done for convenience of explanation only and to provide a general sense of the scope of the invention. Accordingly, unless it is obvious otherwise, such description shall be understood to include one or at least one, and the singular shall also include the plural.

In this disclosure, the terms “first” or “second” and other similar ordinal numbers are mainly used to distinguish or refer to the same or similar elements or structures, and do not necessarily imply that these elements or structures are located in space or time sequence. It should be understood that in certain situations or configurations, ordinal words can be used interchangeably without affecting the implementation of the invention.

In this disclosure, the terms “includes,” “has,” or any other similar terms are intended to cover non-exclusive inclusions. For example, an element or structure containing plural elements is not limited to the elements listed herein, but may include other elements not expressly listed but that are generally inherent to the element or structure.

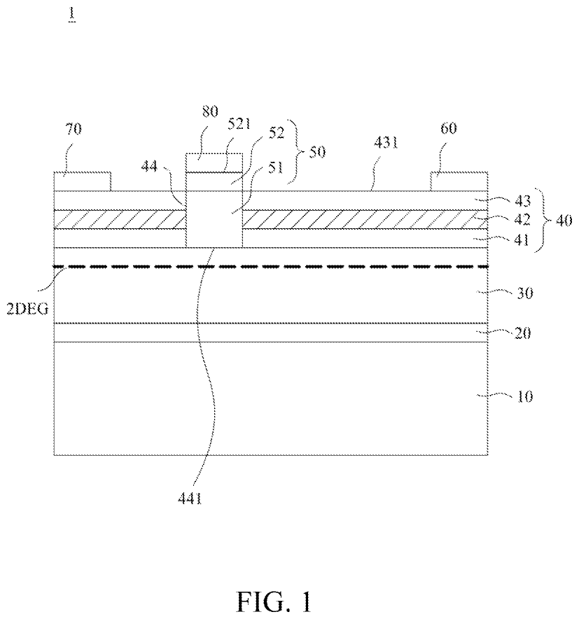

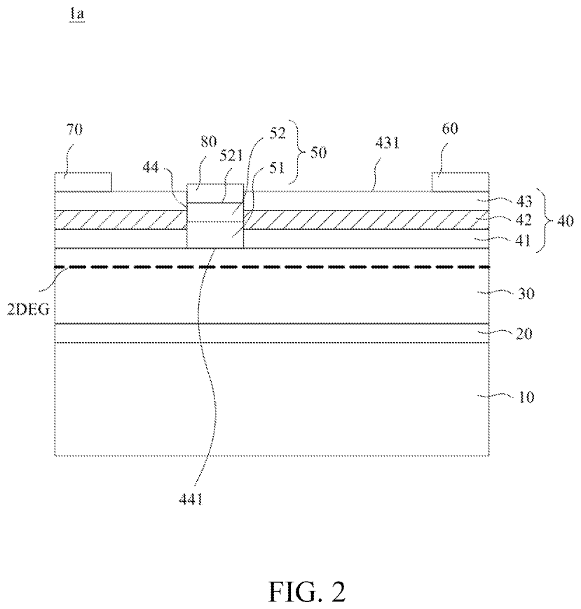

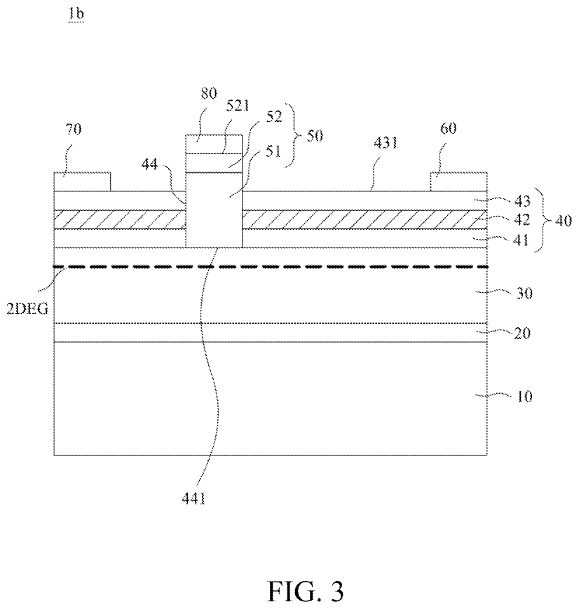

Please refer to FIG. 1 to FIG. 3 together. FIG. 1 is a schematic view of the first embodiment of the high electron mobility transistor of the present invention. FIG. 2 is a schematic view of the second embodiment of the high electron mobility transistor of the present invention. FIG. 3 is a schematic view of the third embodiment of the high electron mobility transistor of the present invention. As shown in FIG. 1 to FIG. 3, the high electron mobility transistors 1, 1a, 1b of the present invention include a substrate 10, a buffer layer 20, a channel layer 30, a first semiconductor epitaxial structure 40, a second semiconductor epitaxial structure 50, a drain 60, a source 70, and a gate 80. The first embodiment shown in FIG. 1 will be used as an example to illustrate the present invention, while the second and third embodiments shown in FIG. 2 and FIG. 3 have similar structures and functions. The substrate 10 serves as the foundational component of the high electron mobility transistor 1. The substrate 10 can be made of materials such as silicon (Si), silicon carbide (SiC), or sapphire, and may also be made of other semiconductor materials. The thickness of the substrate 10 will vary depending on the chip size. For example, in the case of a silicon substrate, the thickness for a 4-inch chip is about 500 μm to 1100 μm, while for a 6-inch chip, it is about 600 μm to 1100 μm.

The buffer layer 20 is located on the substrate 10. The buffer layer 20 serves to deal with the stress on the surface of the substrate 10, facilitating the formation of other semiconductor materials on top of it. The buffer layer 20 can be made of materials such as aluminum nitride (AlN) or other composite materials. The thickness of the buffer layer 20 may vary depending on the design, and can be limited to a range between 10 nm and 4 μm.

The channel layer 30 is located on the buffer layer 20. The channel layer 30 is primarily made of gallium nitride (GaN) material. For example, in one embodiment of the present invention, the channel layer 30 may include a C-doped or Fe-doped gallium nitride layer close to the buffer layer 20, as well as an undoped gallium nitride layer stacked on top of the aforementioned gallium nitride layer and farther away from the buffer layer 20. The undoped gallium nitride layer serves as the primary channel for the two-dimensional electron gas (2DEG). The thickness of the channel layer 30 varies depending on different applications. For instance, when the voltage is at 650V, the thickness of the channel layer 30 is approximately 1.2 μm to 1.5 μm.

The first semiconductor epitaxial structure 40 is located on the channel layer 30. In the present invention, the first semiconductor epitaxial structure 40 sequentially includes a first aluminum gallium nitride layer 41, a supply layer 42, and a second aluminum gallium nitride layer 43. This means that the first aluminum gallium nitride layer 41 is located on the channel layer 30, the supply layer 42 is located on the first aluminum gallium nitride layer 41, and the second aluminum gallium nitride layer 43 is located on the supply layer 42. The first aluminum gallium nitride layer 41 and the second aluminum gallium nitride layer 43 are primarily made of undoped aluminum gallium nitride (AlₓGa₁₋ₓN, where x ranges from 0 to 1, preferably ranges from 0.1 to 0.35) material. The supply layer 42 is mainly used to enhance the electron concentration of the 2DEG. In one embodiment of the present invention, the supply layer 42 can be an N-type aluminum gallium nitride (N—AlₓGa₁₋ₓN) layer, but it can also be made of other materials. The supply layer 42 can be formed through epitaxial growth or ion implantation processes.

In the structural design, a hollow part 44 is formed by photo-lithography etching the first semiconductor epitaxial structure 40. The hollow part 44 extends from the top surface 431 of the second aluminum gallium nitride layer 43 in a direction perpendicular to the top surface 431, towards the channel layer 30. The depth of the aforementioned hollow part 44 can be adjusted according to different requirements. For example, in one embodiment of the present invention, the bottom surface 441 of the hollow part 44 is located between the connection surface of the first aluminum gallium nitride layer 41 and the supply layer 42, and the connection surface of the first aluminum gallium nitride layer 41 and the channel layer 30. For instance, the hollow part 44 may only pass through the supply layer 42 and the second aluminum gallium nitride layer 43, aligning the bottom surface 441 of the hollow part 44 with the connection surface of the first aluminum gallium nitride layer 41 and the supply layer 42 in the same plane. Alternatively, the hollow part 44 may pass through the supply layer 42, the second aluminum gallium nitride layer 43, and partially into the first aluminum gallium nitride layer 41 so that the bottom surface 441 of the hollow part 44 is located between the connection surface of the first aluminum gallium nitride layer 41 and the supply layer 42, and the connection surface of the first aluminum gallium nitride layer 41 and the channel layer 30. Or, the hollow part 44 can also pass through the supply layer 42, the second aluminum gallium nitride layer 43, and the first aluminum gallium nitride layer 41 so that the bottom surface 441 of the hollow part 44 aligns with the connection surface of the first aluminum gallium nitride layer 41 and the channel layer 30 in the same plane.

The second semiconductor epitaxial structure 50 is located within the hollow part 44. In the present invention, the second semiconductor epitaxial structure 50 sequentially includes an aluminum gallium nitride layer 51 and a P-type gallium nitride layer 52. This means that the aluminum gallium nitride layer 51 is located on the channel layer 30 (or the first aluminum gallium nitride layer 41), and the P-type gallium nitride layer 52 is located on the aluminum gallium nitride layer 51. The aluminum gallium nitride layer 51 is primarily made of undoped aluminum gallium nitride material, while the P-type gallium nitride layer 52 is primarily made of P-type gallium nitride material. The thickness of the aluminum gallium nitride layer 51 and the P-type gallium nitride layer 52 may vary depending on different designs. For example, the thickness of the aluminum gallium nitride layer 51 is approximately, but not limited to, 10 nm to 50 nm, and the thickness of the P-type gallium nitride layer 52 is approximately, but not limited to, 1 nm to 100 nm.

In the structural design, the position of the connection surface between the aluminum gallium nitride layer 51 and the P-type gallium nitride layer 52 of the second semiconductor epitaxial structure 50 relative to the top surface 431 of the second aluminum gallium nitride layer 43 of the first semiconductor epitaxial structure 40 will change with the thickness of the aluminum gallium nitride layer 51. In the present invention, the connection surface between the aluminum gallium nitride layer 51 and the P-type gallium nitride layer 52 of the second semiconductor epitaxial structure 50 can be higher than the top surface 431 of the second aluminum gallium nitride layer 43 (as shown in FIG. 3), lower than the top surface 431 of the second aluminum gallium nitride layer 43 (as shown in FIG. 2), or on the same plane as the top surface 431 of the second aluminum gallium nitride layer 43 (as shown in FIG. 1). Preferably, the connection surface between the aluminum gallium nitride layer 51 and the P-type gallium nitride layer 52 of the second semiconductor epitaxial structure 50 is not higher than the top surface 431, so that the P-type gallium nitride layer 52 can provide the ability to form a depleted 2DEG under the zero bias voltage of the gate 80. In this embodiment, in order to simplify the manufacturing process of the high electron mobility transistor 1 of the present invention, the connection surface between the aluminum gallium nitride layer 51 and the P-type gallium nitride layer 52 of the second semiconductor epitaxial structure 50 and the top surface 431 of the second aluminum gallium nitride layer 43 of the first semiconductor epitaxial structure 40 can be formed, but not limited to, on the same plane.

Furthermore, in one embodiment of the present invention, the top surface 431 of the second aluminum gallium nitride layer 43 of the first semiconductor epitaxial structure 40 and the top surface 521 of the P-type gallium nitride layer 52 of the second semiconductor epitaxial structure 50 are not on the same plane. In other words, with the different thicknesses of the aforementioned aluminum gallium nitride layer 51, the position of the top surface 521 of the P-type gallium nitride layer 52 of the second semiconductor epitaxial structure 50 relative to the top surface 431 of the second aluminum gallium nitride layer 43 of the first semiconductor epitaxial structure 40 will also change. In the present invention, the top surface 521 of the P-type gallium nitride layer 52 of the second semiconductor epitaxial structure 50 can be higher than the top surface 431 of the second aluminum gallium nitride layer 43, lower than the top surface 431 of the second aluminum gallium nitride layer 43, or on the same plane as the top surface 431 of the second aluminum gallium nitride layer 43.

The drain 60 and the source 70 are respectively arranged on the top surface 431 of the second aluminum gallium nitride layer 43 of the first semiconductor epitaxial structure 40, and the gate 80 is placed on the top surface 521 of the P-type gallium nitride layer 52 of the second semiconductor epitaxial structure 50.

The high electron mobility transistor 1 of the present invention can form epitaxial structures similar to a depletion-mode HEMT by combining the first semiconductor epitaxial structure 40 with the underlying channel layer 30, and can form epitaxial structures similar to an enhancement-mode HEMT by combining the second semiconductor epitaxial structure 50 with the underlying channel layer 30. The high electron mobility transistor 1 of the present invention utilizes a polarization effect formed between the channel layer 30 and the first aluminum gallium nitride layer 41 of the first semiconductor epitaxial structure 40, as well as between the channel layer 30 and the aluminum gallium nitride layer 51 of the second semiconductor epitaxial structure 50, so that a 2DEG is formed in the channel layer 30 near the first semiconductor epitaxial structure 40 and the second semiconductor epitaxial structure 50.

It can be understood that by setting the supply layer 42 in the first semiconductor epitaxial structure 40, the electron concentration of the 2DEG within the channel layer 30 is enhanced. When the gate voltage is biased at zero, the electron concentration of the 2DEG in the channel layer 30 is very low due to the depletion of the built-in electric field in the second semiconductor epitaxial structure 50. As a forward bias is applied to the gate 80, the electron concentration of the 2DEG in the channel layer 30 beneath the second semiconductor epitaxial structure 50 increases, thereby causing the high electron mobility transistor 1 of the present invention to turn on effectively. Therefore, the high electron mobility transistor 1 of the present invention combines the advantages of both a depletion-mode HEMT and an enhancement-mode HEMT, making it more advantageous compared to conventional depletion-mode HEMTs and/or enhancement-mode HEMTs.

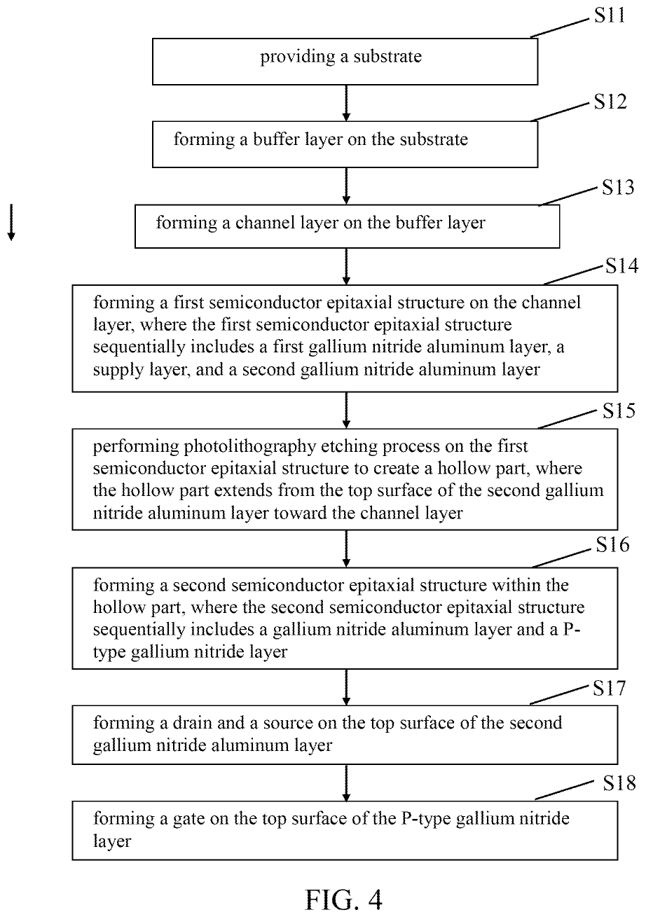

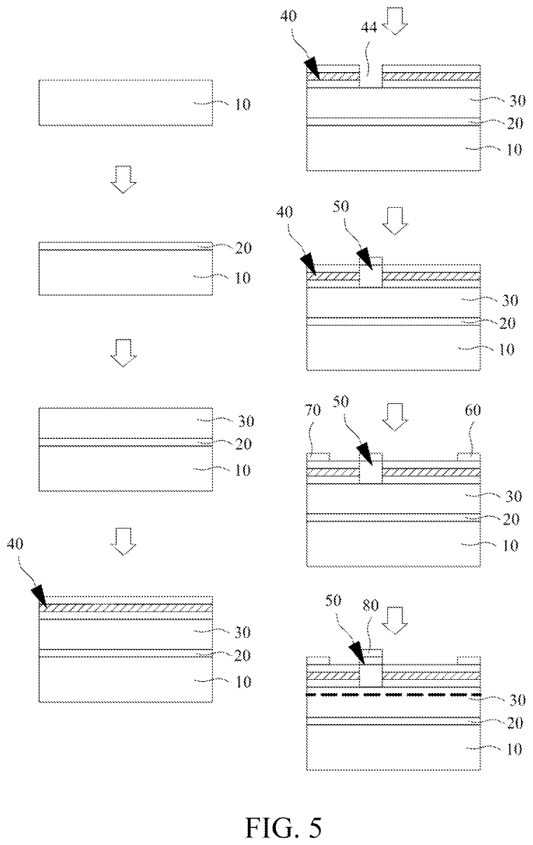

Please also refer to FIG. 4 and FIG. 5. FIG. 4 is a flowchart of a first embodiment of the fabricating method for the high electron mobility transistor of the present invention, and FIG. 5 is a schematic view of the structural process corresponding to FIG. 4. As shown in FIG. 4 and FIG. 5, the fabricating method for the high electron mobility transistor of the present invention includes the following steps S11 to S18.

Step S11: Providing a substrate.

Initially, the present invention utilizes a substrate 10 as the foundational component for the high electron mobility transistor 1 of the present invention.

Step S12: Forming a buffer layer on the substrate.

After providing the substrate 10 in the previous Step S11, the present invention subsequently executes an epitaxial (EPI) process using materials like aluminum nitride on one side of the substrate 10 to form a buffer layer 20 on the substrate 10. This is done to deal with stresses on the surface of the substrate 10, benefit to the subsequent processes.

Step S13: Forming a channel layer on the buffer layer.

After forming the first semiconductor layer 20 in the previous Step S12, the present invention can carry out another epitaxial process using gallium nitride material on the buffer layer 20 to form a channel layer 30 on the buffer layer 20.

Step S14: Forming a first semiconductor epitaxial structure on the channel layer, where the first semiconductor epitaxial structure sequentially includes a first gallium nitride aluminum layer, a supply layer, and a second gallium nitride aluminum layer.

After forming the channel layer 30 in the previous Step S13, the present invention can execute multiple epitaxial processes on the exposed side surface of the channel layer 30. This results in the sequential formation of a first gallium nitride aluminum layer 41, a supply layer 42, and a second gallium nitride aluminum layer 43 on the channel layer 30, thereby the whole first semiconductor epitaxial structure 40 is formed.

Step S15: Performing photolithography etching process on the first semiconductor epitaxial structure to create a hollow part, where the hollow part extends from the top surface of the second gallium nitride aluminum layer toward the channel layer.

Following the previous Step S14, the present invention can carry out a photolithography etching process on the first semiconductor epitaxial structure 40. A hollow part 44 is formed on the first semiconductor epitaxial structure 40. The hollow part 44 extends from the top surface 431 of the second gallium nitride aluminum layer 43 toward the channel layer 30, and the bottom surface 441 of the hollow part 44 is located between the connection surface of the first gallium nitride aluminum layer 41 and the supply layer 42, and the connection surface of the first gallium nitride aluminum layer 41 and the channel layer 30.

Step S16: Forming a second semiconductor epitaxial structure within the hollow part, where the second semiconductor epitaxial structure sequentially includes a gallium nitride aluminum layer and a P-type gallium nitride layer.

After forming the hollow part 44 in the previous Step S15, the present invention can execute multiple epitaxial processes within the hollow part 44. This results in the sequential formation of a gallium nitride aluminum layer 51 and a P-type gallium nitride layer 52 on the bottom surface 441 of the hollow part 44, thereby the whole second semiconductor epitaxial structure 50 is formed.

Step S17: Forming a drain and a source on the top surface of the second gallium nitride aluminum layer.

The present invention can execute a metallization process on the top surface 431 of the second gallium nitride aluminum layer 43 of the first semiconductor epitaxial structure 40. In this process, the drain 60 and the source 70 are formed respectively on the top surface 431 of the second gallium nitride aluminum layer 43.

Step S18: Forming a gate on the top surface of the P-type gallium nitride layer.

The present invention can execute a metallization process on the top surface 521 of the P-type gallium nitride layer 52 of the second semiconductor epitaxial structure 50. In this process, the gate 80 is formed on the top surface 521 of the P-type gallium nitride layer 52.

It is noted that the execution order of the aforementioned Step S17 and Step S18 can be adjusted according to process requirements.

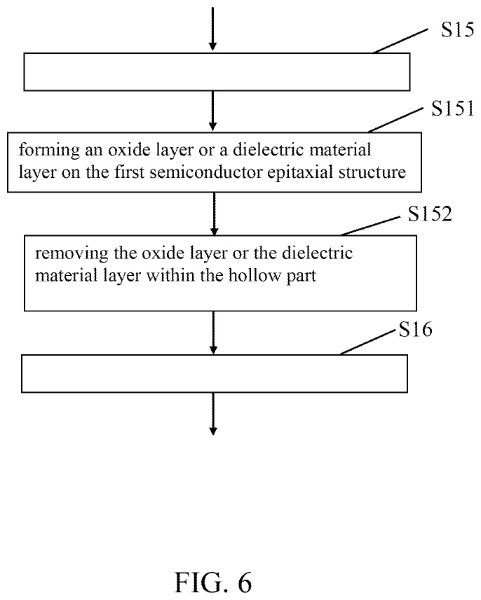

Please refer to FIG. 6 for a partial process flow chart of the second embodiment of the fabricating method for the high electron mobility transistor of the present invention. As shown in FIG. 6, in order to prevent the epitaxial process of the second semiconductor epitaxial structure 50 from affecting the already existed first semiconductor epitaxial structure 40, the method for fabricating the high electron mobility transistor of the present invention further includes steps S151 and S152 before step S16.

Step S151: Forming an oxide layer or a dielectric material layer on the first semiconductor epitaxial structure.

After forming the hollow part 44 in the previous Step S15, the present invention can carry out an evaporation process on the first semiconductor epitaxial structure 40 to form an oxide layer (e.g., SiO₂ or Al₂O₃) or a dielectric material layer on the surface of the first semiconductor epitaxial structure 40 to protect it.

Step S152: Removing the oxide layer or the dielectric material layer within the hollow part.

After forming the oxide layer or the dielectric material layer in the previous Step S151, the present invention can execute another photolithography etching process on the hollow part 44 to remove the oxide layer or the dielectric material layer within the hollow part 44. Because the other parts of the first semiconductor epitaxial structure 40, apart from the hollow part 44, are protected by the oxide layer or the dielectric material layer, the subsequent epitaxial process of the second semiconductor epitaxial structure 50 will not affect the existed first semiconductor epitaxial structure 40. A single crystal orientation epitaxial structure can be formed only within the hollow part 44.

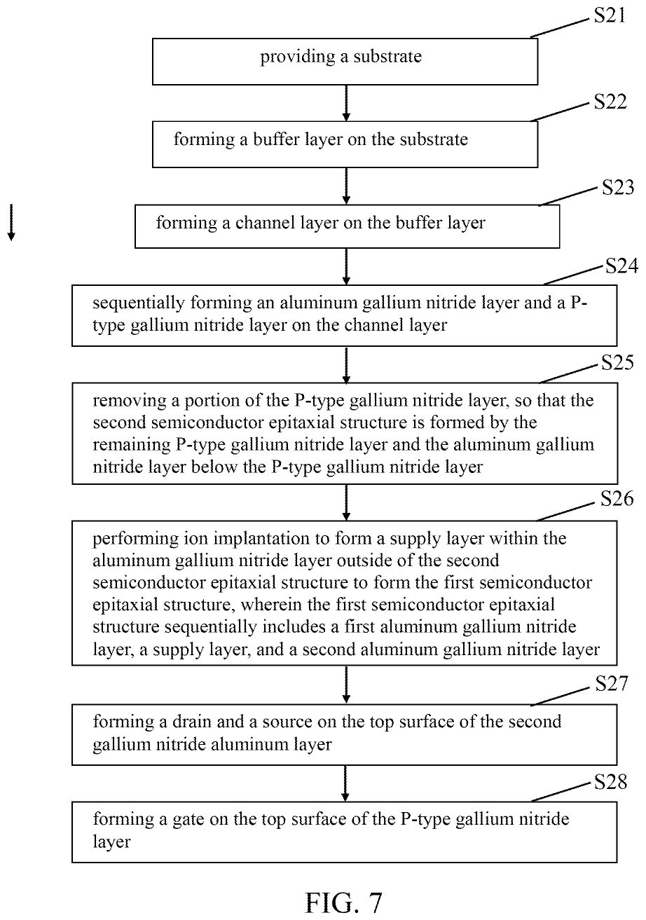

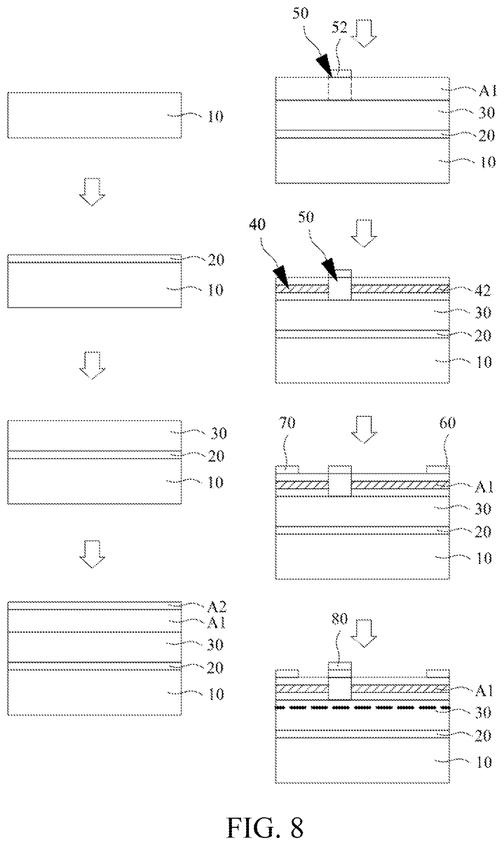

Please refer to FIG. 7 and FIG. 8 for a process flow chat and a corresponding structural process diagram of the third embodiment of the method for fabricating the high electron mobility transistor of the present invention. As shown in FIG. 7 and FIG. 8, in another embodiment of the present invention, the method for fabricating the high electron mobility transistor of the present invention includes the following steps S21 to S28. Since steps S21 to S23 and steps S27 to S28 are the same as steps S11 to S13 and steps S17 to S18 described above, they will be neglected in the followings.

Step S24: Sequentially forming an aluminum gallium nitride layer and a P-type gallium nitride layer on the channel layer.

After forming the channel layer 30 in the previous step, the present invention can perform multiple epitaxial processes to sequentially form an aluminum gallium nitride layer 51 and a P-type gallium nitride layer 52 on the exposed surface of the channel layer 30.

Step S25: Removing a portion of the P-type gallium nitride layer, so that the second semiconductor epitaxial structure is formed by the remaining P-type gallium nitride layer and the aluminum gallium nitride layer below the P-type gallium nitride layer.

After forming the aluminum gallium nitride layer A1 and the P-type gallium nitride layer A2 in step S24, the present invention can carry out a photolithography etching process on the unnecessary part of the P-type gallium nitride layer A2 to remove a portion of the it and the P-type gallium nitride layer 52 acted as the second semiconductor epitaxial structure 50 will be remained. Accordingly, the second semiconductor epitaxial structure 50 will be formed by the P-type gallium nitride layer 52 and the aluminum gallium nitride layer 51 beneath it.

Step S26: Performing ion implantation to form a supply layer within the aluminum gallium nitride layer outside of the second semiconductor epitaxial structure to form the first semiconductor epitaxial structure. The first semiconductor epitaxial structure sequentially includes a first aluminum gallium nitride layer, a supply layer, and a second aluminum gallium nitride layer.

After forming the second semiconductor epitaxial structure 50 in Step S25, the present invention can carry out an ion implantation process on the aluminum gallium nitride layer A1 outside of the second semiconductor epitaxial structure 50. N-type ions are implanted into the aluminum gallium nitride layer A1 to form the supply layer 42. The aluminum gallium nitride layer A1 is separated into the first aluminum gallium nitride layer 41 and the second aluminum gallium nitride layer 43 by the supply layer 42. And thus, the first semiconductor epitaxial structure 40 is formed. The first semiconductor epitaxial structure 40 on the channel layer 30 sequentially includes the first aluminum gallium nitride layer 41, the supply layer 42, and the second aluminum gallium nitride layer 43.

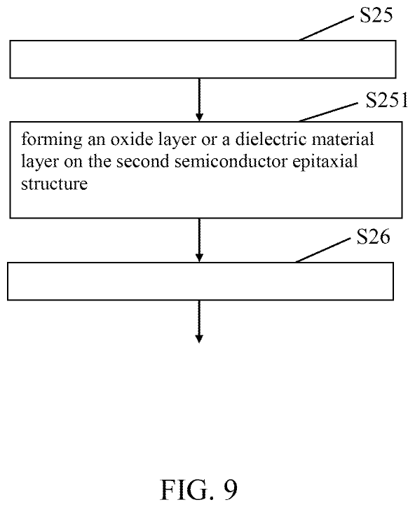

Please refer to FIG. 9 for a partial process flow chart of the fourth embodiment of the manufacturing method for the high electron mobility transistor of the present invention. As shown in FIG. 9, in order to prevent the ion implantation process of the supply layer 42 in the first semiconductor epitaxial structure 40 from affecting the existed second semiconductor epitaxial structure 50, the method for fabricating the high electron mobility transistor of the present invention further includes step S251 before step S26.

Step S251: Forming an oxide layer or a dielectric material layer on the second semiconductor epitaxial structure.

After forming the second semiconductor epitaxial structure 50 in step S25, the present invention can perform an evaporation process on the second semiconductor epitaxial structure 50. An oxide layer (such as SiO₂or Al₂O₃) or a dielectric material layer is formed on the top surface 521 of the P-type gallium nitride layer 52 in the second semiconductor epitaxial structure 50 to protect the second semiconductor epitaxial structure 50.

The above embodiments are provided for illustrative purposes and are not intended to limit the embodiments or their applications or uses. Additionally, although at least one exemplary embodiment has been presented in the above embodiments, it should be understood that the present invention can have many variations. It should also be understood that the embodiments described herein are not intended to limit the scope, application, or configuration of the claimed subject matter in any way. On the contrary, the embodiments described above can provide a convenient guide for those skilled in the art to implement one or more embodiments. Furthermore, various changes can be made to the functionality and arrangement of the components without departing from the scope defined by the claims, and the claims encompass known equivalents and foreseeable equivalents at the time of filing of this patent application.

What is claimed is:

1. A high electron mobility transistor, including:
a substrate;
a buffer layer located on the substrate;
a channel layer located on the buffer layer;
a first semiconductor epitaxial structure located on the channel layer and sequentially including a first aluminum gallium nitride layer, a supply layer and a second aluminum gallium nitride layer, and the first semiconductor epitaxial structure being formed with a hollow part, and the hollow part extending from a top surface of the second aluminum gallium nitride layer toward the channel layer;
a second semiconductor epitaxial structure located in the hollow part and sequentially including an aluminum gallium nitride layer and a P-type gallium nitride layer;
a drain and a source respectively arranged on the top surface of the second aluminum gallium nitride layer; and
a gate arranged on a top surface of the P-type gallium nitride layer.

2. The high electron mobility transistor of claim 1, wherein the top surface of the second aluminum gallium nitride layer of the first semiconductor epitaxial structure and the top surface of the P-type gallium nitride layer are not on the same plane.

3. The high electron mobility transistor of claim 1, wherein the top surface of the second aluminum gallium nitride layer of the first semiconductor epitaxial structure and the connection surface between the aluminum gallium nitride layer and the P-type gallium nitride layer of the second semiconductor epitaxial structure are not on the same plane.

4. The high electron mobility transistor of claim 1, wherein the connection surface between the aluminum gallium nitride layer and the P-type gallium nitride layer of the second semiconductor epitaxial structure is not higher than the top surface of the second aluminum gallium nitride layer of the first semiconductor epitaxial structure.

5. The high electron mobility transistor of claim 1, wherein the supply layer is an N-type aluminum gallium nitride layer.

6. The high electron mobility transistor of claim 1, wherein a bottom surface of the hollow part is between the connection surface of the first aluminum gallium nitride layer and the supply layer, and the connection surface of the first aluminum gallium nitride layer and the channel layer.

7. The high electron mobility transistor of claim 1, wherein the thickness of the aluminum gallium nitride layer of the second semiconductor epitaxial structure is from 10 nm to 50 nm, and the thickness of the P-type gallium nitride layer is from 1 nm to 100 nm.

8. A method for fabricating a high electron mobility transistor, including:
providing a substrate;
providing a buffer layer located on the substrate;
providing a channel layer located on the buffer layer;
forming a first semiconductor epitaxial structure located on the channel layer, wherein the first semiconductor epitaxial structure sequentially includes a first aluminum gallium nitride layer, a supply layer and a second aluminum gallium nitride layer;
forming a hollow part by photolithography etching the first semiconductor epitaxial structure, wherein the hollow part extends from a top surface of the second aluminum gallium nitride layer toward the channel layer;
forming a second semiconductor epitaxial structure located in the hollow part, wherein the second semiconductor epitaxial structure sequentially includes an aluminum gallium nitride layer and a P-type gallium nitride layer;
forming a drain and a source respectively arranged on the top surface of the second aluminum gallium nitride layer; and
forming a gate arranged on a top surface of the P-type gallium nitride layer.

9. The method for fabricating a high electron mobility transistor of claim 8, before the step of forming a second semiconductor epitaxial structure located in the hollow part, further including:
forming an oxide layer or a dielectric layer on the first semiconductor epitaxial structure; and
removing the oxide layer or the dielectric layer located in the hollow part.

10. A method for fabricating a high electron mobility transistor, including:
providing a substrate;
providing a buffer layer located on the substrate;
providing a channel layer located on the buffer layer;
sequentially forming an aluminum gallium nitride layer and a P-type gallium nitride layer;
removing a part of the P-type gallium nitride layer so that a second semiconductor epitaxial structure is formed by the remaining part of the P-type gallium nitride layer and the aluminum gallium nitride layer under the P-type gallium nitride layer;
performing an ion implantation process to form a supply layer in the aluminum gallium nitride layer outside the second semiconductor epitaxial structure for forming a first semiconductor epitaxial structure, wherein the first semiconductor epitaxial structure sequentially includes a first aluminum gallium nitride layer, the supply layer and a second aluminum gallium nitride layer;
forming a drain and a source respectively arranged on a top surface of the second aluminum gallium nitride layer; and
forming a gate arranged on a top surface of the P-type gallium nitride layer.

11. The method for fabricating a high electron mobility transistor of claim 10, before the step of performing the ion implantation process, further including:
forming an oxide layer or a dielectric layer on the second semiconductor epitaxial structure.
